(19) United States
(12) Patent Application Publication
(10) Pub. No.: US 2025/0221136 A1
(43) Pub. Date: Jul. 3, 2025

(54) ELECTRONIC DEVICE AND MANUFACTURING METHOD THEREOF

(71) Applicant: Innolux Corporation, Miaoli County (TW)

(72) Inventors: Tsau-Hua Hsieh, Miaoli County (TW); Kuan-Hung Kuo, Miaoli County (TW); Chiung-Chieh Kuo, Miaoli County (TW); Shu-Han Yu, Miaoli County (TW); Yan-Yu Qiu, Miaoli County (TW); Bo-Jun Jiang, Miaoli County (TW)

(73) Assignee: Innolux Corporation, Miaoli County (TW)

(21) Appl. No.: 18/970,855

(22) Filed: Dec. 5, 2024

(30) Foreign Application Priority Data
Jan. 3, 2024 (CN) 202410007906.X

(51) Int. Cl. H10H 29/855; H10H 29/01; H10H 29/24; H10H 29/85

(52) U.S. Cl. CPC H10H 29/8552; H10H 29/0363; H10H 29/0364; H10H 29/24; H10H 29/8506; H10H 29/857

(57) ABSTRACT

An electronic device includes a first substrate, a first circuit layer, a second circuit layer, a side circuit layer, a light-shielding layer, a protective layer, and a circuit board. The first substrate has a first surface, a second surface, and a side surface. The first surface is opposite to the second surface. The side surface connects the first surface and the second surface. The first circuit layer is disposed on the first surface. The second circuit layer is disposed on the second surface. The side circuit layer is disposed on the side surface and electrically connected to the first circuit layer and the second circuit layer. The light-shielding layer is disposed on the side circuit layer. The protective layer is disposed on the light-shielding layer and the second circuit layer, and continuously extends from the side surface to the second surface. The protective layer includes an opening exposing a portion of the second circuit layer. The circuit board is electrically connected to the second circuit layer through the opening.

### CROSS-REFERENCE TO RELATED APPLICATION

This application claims the priority benefit of China application serial no. 202410007906.X, filed on Jan. 3, 2024. The entirety of the above-mentioned patent application is hereby incorporated by reference herein and made a part of this specification.

### BACKGROUND

### Technical Field

This disclosure relates to an electronic device and a manufacturing method of the electronic device.

### Description of Related Art

With the vigorous development of an electronic product, requirements for display quality of the electronic product have also increased. For example, an electronic device used for display is constantly improving towards display effects of higher resolution and/or contrast. Therefore, on the premise of improving the display effect of the electronic device, how to optimize a process of forming the electronic device is one of important issues in the art.

### SUMMARY

Some embodiments of the disclosure are directed to an electronic device whose display effect may be improved.

According to some embodiments of the disclosure, an electronic device includes a first substrate, a first circuit layer, a second circuit layer, a side circuit layer, a light-shielding layer, a protective layer, and a circuit board. The first substrate has a first surface, a second surface, and a side surface. The first surface is opposite to the second surface, and the side surface connects the first surface and the second surface. The first circuit layer is disposed on the first surface. The second circuit layer is disposed on the second surface. The side circuit layer is disposed on the side surface and is electrically connected to the first circuit layer and the second circuit layer. The light-shielding layer is disposed on the side circuit layer. The protective layer is disposed on the light-shielding layer and the second circuit layer, and continuously extends from the side surface to the second surface. The protective layer includes an opening exposing a portion of the second circuit layer. The circuit board is electrically connected to the second circuit layer through the opening.

Some embodiments of the disclosure are directed to a manufacturing method of an electronic device, which has a simplified number of process steps and may reduce process cost of the electronic device.

According to some embodiments of the disclosure, a manufacturing method of an electronic device includes the following steps. A first substrate is provided. The first substrate has a first surface, a second surface, and a side surface. The first surface is opposite to the second surface, and the side surface connects the first surface and the second surface. A circuit structure is formed on the first surface, the second surface, and the side surface. A first shielding layer is formed on the second surface. A light-shielding layer is formed on the side surface. The first shielding layer is removed. A second shielding layer is formed on a connection portion of the circuit structure located on the second surface. A protective layer is formed on the side surface, the second surface, and the second shielding layer. The second shielding layer is removed to expose the connection portion of the circuit structure. A circuit board is bonded to the connection portion of the circuit structure.

According to other embodiments of the disclosure, a manufacturing method of an electronic device includes the following steps. A first substrate is provided. The first substrate has a first surface, a second surface, and a side surface. The first surface is opposite to the second surface, and the side surface connects the first surface and the second surface. A circuit structure is formed on the first surface, the second surface, and the side surface. A first shielding layer is formed on the second surface. A light-shielding layer and a protective layer are sequentially formed on the side surface and the second surface. The first shielding layer is removed. A second shielding layer is formed on the second surface. The second shielding layer exposes a connection portion of the circuit structure. A circuit board is bonded to the connection portion of the circuit structure.

Based on the above, in the disclosure, one process may be performed to form the protective layer on both the side surface and the second surface of the first substrate, which may reduce the number of process steps for forming the electronic device according in the disclosure, and reduce the process cost of the electronic device. Furthermore, through the design of forming the protective layer on both the side surface and the second surface of the first substrate, the protective layer may continuously extend from the side surface to the second surface, so that the electronic device may reduce a phenomenon of side light leakage, which may improve the display effect of the tiling electronic device.

### BRIEF DESCRIPTION OF THE DRAWINGS

FIG. 1 is a schematic flowchart of a manufacturing method of an electronic device according to an embodiment of the disclosure.

FIG. 2A and FIG. 2B are schematic partial cross-sectional views of shielding layers according to an embodiment of the disclosure.

FIG. 3 is a schematic partial cross-sectional view of an electronic device according to an embodiment of the disclosure.

FIG. 4 is a schematic partial cross-sectional view of an electronic device according to another embodiment of the disclosure.

FIG. 5 is a schematic flowchart of a manufacturing method of an electronic device according to another embodiment of the disclosure.

### DETAILED DESCRIPTION OF DISCLOSED EMBODIMENTS

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

The disclosure can be understood by referring to the following detailed description in combination with the accompanying drawings. It should be noted that in order to make it easy for the reader to understand and for the simplicity of the drawings, the multiple drawings in this disclosure only depict a part of the electronic device, and the specific components in the drawings are not drawn according to actual scale. In addition, the number and size of each component in the drawings are only for exemplary purpose, and are not intended to limit the scope of the disclosure.

Throughout the disclosure and the appended claims, certain words are used to refer to specific components. Those skilled in the art should understand that electronic device manufacturers may refer to the same components by different names. The disclosure does not intend to distinguish those components with the same function but different names. In the following description and claims, the terms “include”, “contain”, and “have” are open-ended terms, so they should be interpreted as “include but not limited to . . . ”. Therefore, when the terms “including”, “containing”, and/or “having” are used in the description of this disclosure, they specify the existence of a corresponding feature, region, step, operation, and/or component, but do not exclude the existence of one or more corresponding features, regions, steps, operations, and/or components.

Direction terms mentioned in this specification, such as such as “up,” “down,” “front,” “back,” “left,” and “right,” merely refer to directions in the accompanying drawings. Therefore, the direction terms used is for illustration, not for limiting this disclosure. In the drawings, each drawing shows the general features of the method, structure, and/or material used in a specific embodiment. However, these drawings should not be construed as defining or limiting the scope or nature of the embodiments. For example, for the sake of clarity, the relative size, thickness, and position of each layer, region, and/or structure may be reduced or enlarged.

When a corresponding member (such as a layer or a region) is described as being “on another member,” it may be directly on another member, or there may be other member therebetween. On the other hand, when a member is described as being “directly on another member,” no member exists therebetween unless otherwise stated in the specification. In addition, when a member is described as being “on another member,” the two have a vertical relationship in the top view direction, and this member may be located above or below the other member, and the vertical relationship depends on the device orientation.

The terms “equal to” or “same” and “essentially” or “substantially” are generally interpreted as within 20% of a given value or range, or as within 10%, 5%, 3%, 2%, 1%, or 0.5% of the value or range.

Ordinal numbers in this specification and the claims such as “first” and “second” are used to modify a component, and do not imply or represent that the (or these) component(s) has (or have) any ordinal number, and do not indicate any order between a component and another component, or an order in a manufacturing method. These ordinal numbers are merely used to clearly distinguish a component having a name with another component having the same name. Different terms may be used in the claims and the specification, so that a first member in the specification may be a second member in the claims.

It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

An electrical connection or coupling relationship described in this disclosure may refer to a direct connection or an indirect connection. In the case of the direct connection, end points of the elements on two circuits are directly connected or connected to each other by a conductor segment, and in the case of the indirect connection, there are switches, diodes, capacitors, inductors, resistors, other appropriate elements, or a combination of the above elements between the end points of the elements on the two circuits, but the disclosure is not limited thereto.

In the disclosure, the thickness, length, width, and area may be measured by an optical microscope, and the thickness may be measured from a cross-sectional image in an electron microscope, but the disclosure is not limited thereto. In addition, a certain error may be provided between any two values or directions used for comparison. If the first value is equal to the second value, it implies that an error of approximately 10% is provided between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

The electronic device in the disclosure may be applied to tiling devices, display devices, light emitting devices, backlight devices, virtual reality devices, augmented reality devices, antenna devices, or sensing devices, but the disclosure is not limited thereto. The electronic device may be a bendable or flexible electronic device. The electronic device may include, for example, liquid crystals, light emitting diodes, fluorescence, phosphor, other suitable display media, or a combination of the above, but the disclosure is not limited thereto. The display device may be a non-self-luminous display device or a self-luminous display device. The antenna device may be a liquid crystal antenna device or a non-liquid crystal antenna device, and the sensing device may be a sensing device that senses capacitance, light, heat energy, or ultrasonic waves, but the disclosure is not limited thereto. The electronic device may include, for example, electronic elements such as passive devices and active devices, such as capacitors, resistors, inductors, diodes, transistors. The diode may include light emitting diodes or photodiodes. The light emitting diode may include, for example, organic light emitting diodes (OLEDs), mini LEDs, micro LEDs, or quantum dot LEDs, but the disclosure is not limited thereto. The tiling device may be, for example, a display tiling device or an antenna tiling device, but the disclosure is not limited thereto. It should be noted that the electronic device may be any arrangement and combination of the above, but the disclosure is not limited thereto. In addition, a shape of the electronic device may be a rectangle, a circle, a polygon, a shape with curved edges, or other suitable shapes. The electronic device may have peripheral systems such as driving systems, control systems, and light source systems to support the display devices, antenna devices, wearable devices (for example, including augmented reality or virtual reality), vehicle devices (for example, including vehicle windshields), or tiling devices.

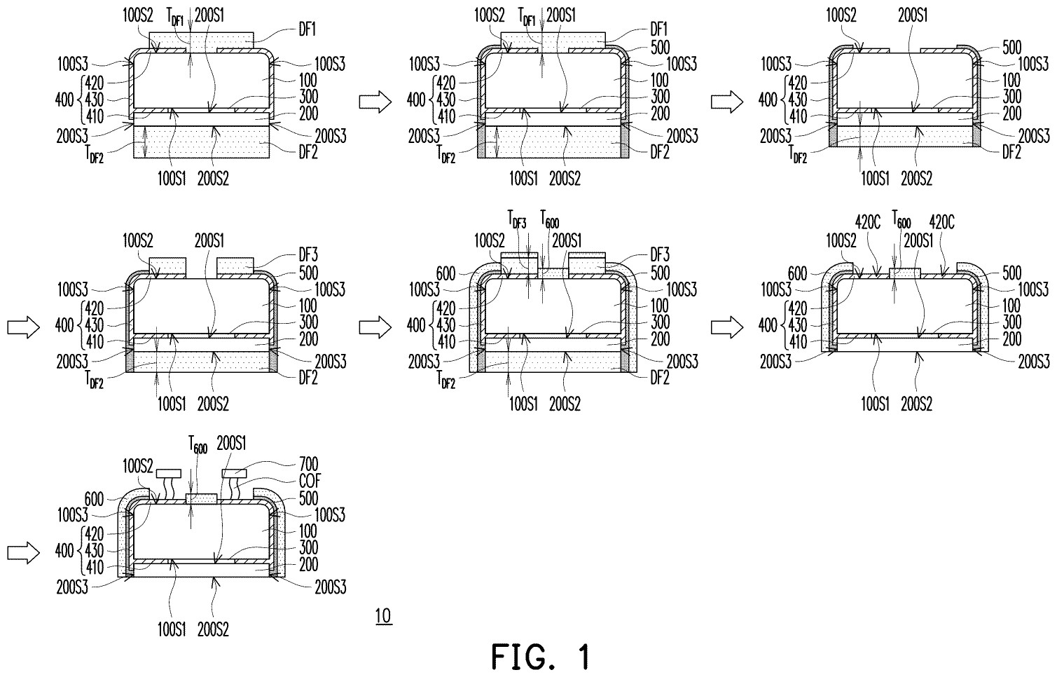

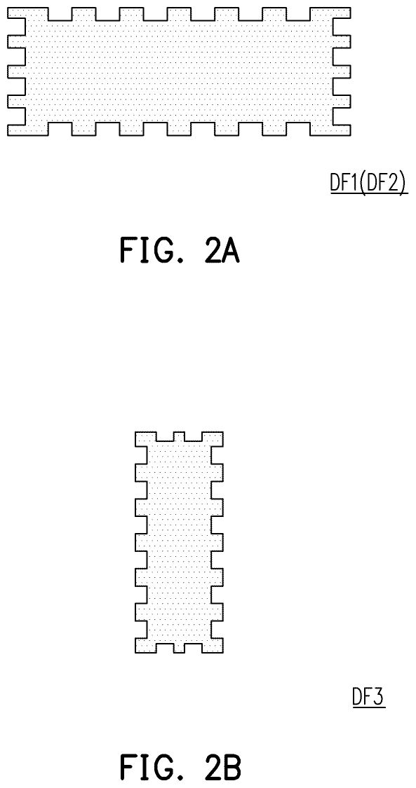

FIG. 1 is a schematic flowchart of a manufacturing method of an electronic device according to an embodiment of the disclosure. FIG. 2A and FIG. 2B are schematic partial cross-sectional views of shielding layers according to an embodiment of the disclosure.

Referring to FIG. 1, in this embodiment, an electronic device 10 may be formed by performing the following steps, but the disclosure is not limited thereto.

Step (1): A first substrate 100 and a second substrate 200 are provided, and the first substrate 100 and the second substrate 200 are bonded together.

The first substrate 100 is, for example, an active device array substrate. In detail, the first substrate 100 may include, for example, a first base (not shown) and an active device (not shown). A detailed structure thereof will be described in detail in the following embodiments, which will not be further reiterated here.

The first substrate 100 has, for example, a first surface 100S1, a second surface 100S2, and multiple side surfaces 100S3. The first surface 100S1 is opposite to the second surface 100S2, and the side surface 100S3 connects the first surface 100S1 and the second surface 100S2.

The second substrate 200 is, for example, a color filter substrate. In detail, the second substrate 200 may include, for example, a second base (not shown) and a color filter (not shown). A detailed structure thereof will be described in detail in the following embodiments, which will not be further reiterated here.

The second substrate 200 has, for example, a first surface 200S1, a second surface 200S2, and multiple side surfaces 200S3. The first surface 200S1 is opposite to the second surface 200S2, and the side surface 200S3 connects the first surface 200S1 and the second surface 200S2. In this embodiment, the first surface 200S1 of the second substrate 200 faces the first surface 100S1 of the first substrate 100.

It is worth noting that although the electronic device 10 shown in this embodiment will include a double-board structure, the electronic devices in other embodiments of the disclosure may include a single-board structure.

In this embodiment, a display medium layer 300 may be further disposed between the first substrate 100 and the second substrate 200. A structure and/or composition of the display medium layer 300 will be described in detail in the following embodiments, which will not be further reiterated here.

Step (2): A circuit structure 400 is formed on the first surface 100S1, the second surface 100S2, and the side surfaces 100S3 of the first substrate 100.

The circuit structure 400 may include, for example, multiple traces (not shown) and multiple pads (not shown), but the disclosure is not limited thereto. In this embodiment, the circuit structure 400 includes a first circuit layer 410 disposed on the first surface 100S1, a second circuit layer 420 disposed on the second surface 100S2, and a side circuit layer 430 disposed on the side surface 100S3. The second circuit layer 420 may include a connection portion 420C, which may be used, for example, to be electrically connected to an external circuit board (e.g., a circuit board 700 in this embodiment), so that corresponding elements in the first substrate 100 and/or the second substrate 200 may be electrically connected to the external circuit board. However, the disclosure is not limited thereto.

In this embodiment, the side circuit layer 430 of the circuit structure 400 may further extend to the side surface 200S3 of the second substrate 200, but the disclosure is not limited thereto.

Step (3): A shielding layer DF1 is formed on the second surface 100S2 of the first substrate 100, and a shielding layer DF2 is formed on a surface (the second surface 200S2) of the second substrate 200 away from the first substrate 100.

In some embodiments, the shielding layer DF1 and the shielding layer DF2 may be respectively formed by performing an attaching process or a coating process. For example, the shielding layer DF1 and the shielding layer DF2 may be respectively formed by performing the attaching process, a spraying process, a silk-screen printing process, or other suitable processes. The disclosure is not limited thereto.

In some embodiments, a material of the shielding layer DF1 may include a dry film or a wet film. In this embodiment, the material of the shielding layer DF1 includes the dry film. For example, the material of the shielding layer DF1 may include polyethylene terephthalate (PET), polyether styrene (PES), polyethylene naphthalate (PEN), polycarbonate (PC), polyimide (PI) or a combination thereof, but the disclosure is not limited thereto.

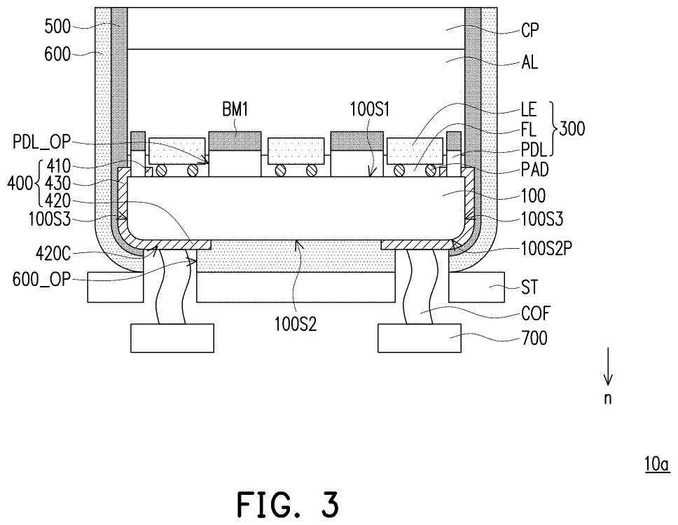

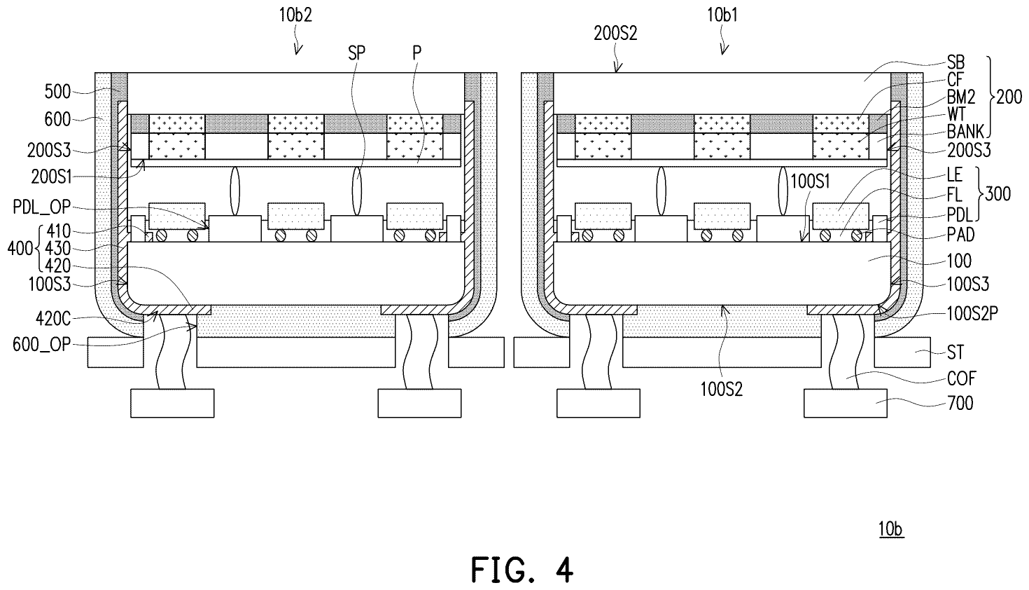

In this embodiment, the shielding layer DF1 roughly covers the second surface 100S2 of the first substrate 100, but exposes a peripheral portion of the second surface 100S2 (e.g., a peripheral portion 100S2P shown in FIG. 3 and FIG. 4). The peripheral portion is adjacent to a junction of the side surface 100S3 and the second surface 100S2. On this basis, the shielding layer DF1 may be used, for example, to define a formation position of a subsequent light-shielding layer 500, so that the light-shielding layer 500 may be disposed on, for example, the side surface 100S3 and the peripheral portion of the second surface 100S2 of the first substrate 100.

In this embodiment, the shielding layer DF2 covers the second surface 200S2 of the second substrate 200. That is, an edge of the shielding layer DF2 is flush with the second surface 200S2 of the second substrate 200. On this basis, the shielding layer DF2 may, for example, reduce a phenomenon of glue bleeding in the second substrate 200 during subsequent processes. Furthermore, the shielding layer DF2 may also be used to define the formation position of the subsequent light-shielding layer 500, so that the light-shielding layer 500 may be, for example, disposed on the side surface 200S3 of the second substrate 200.

A material of the shielding layer DF2 may be, for example, the same as or similar to the material of the shielding layer DF1, which will not be further reiterated here.

In this embodiment, a thickness T_{DF2} of the shielding layer DF2 is greater than a thickness T_{DF1} of the shielding layer DF1, so as to retain a portion of the shielding layer DF2 when the shielding layer DF1 is subsequently removed, which will be described in detail in subsequent embodiments and will not be further reiterated here. In some embodiments, the thickness T_{DF2} of the shielding layer DF2 is 40 microns to 200 microns, and the thickness T_{DF1} of the shielding layer DF1 is 20 microns to 100 microns.

In some embodiments, at least one of the shielding layer DF1 and the shielding layer DF2 may have a non-linear edge. For example, referring to FIG. 2A, the shielding layer DF1 and the shielding layer DF2 have bow-shaped edges. By enabling the shielding layer DF1 and/or the shielding layer DF2 to have the non-linear edges, surface areas of the shielding layer DF1 and/or the shielding layer DF2 may be increased to increase a possibility of subsequent complete removal of the shielding layer DF1 and/or the shielding layer DF2. In this way, a possibility that subsequent processes will be affected by residue of the shielding layer DF1 and/or the shielding layer DF2 may be reduced.

Step (4): The light-shielding layer 500 is formed on the side surface 100S3 of the first substrate 100 and the side surface 200S3 of the second substrate 200.

As mentioned above, the formation position of the light-shielding layer 500 may be defined by the configuration of the shielding layer DF1 and the shielding layer DF2, which will not be further reiterated here. In addition, the light-shielding layer 500 may be used to reduce a possibility that the elements and/or the circuit structure 400 in the first substrate 100 and the second substrate 200 are observed by a user or a possibility of light leaking from the side surface 100S3 of the first substrate 100 and the side surface 200S3 of the second substrate 200.

In this embodiment, the light-shielding layer 500 may cover the first substrate 100 and the second substrate 200 together with the shielding layer DF1 and the shielding layer DF2, but the disclosure is not limited thereto.

It is worth noting that, in order to reduce a possibility of the light-shielding layer 500 being removed in subsequent steps (5) and/or (6), the light-shielding layer 500 includes a material with relatively high chemical resistance. For example, a material of the light-shielding layer 500 may be resistant to corrosion by a stripper and/or developer.

Step (5): The shielding layer DF1 and a portion of the shielding layer DF2 are removed.

In this embodiment, the shielding layer DF1 and a portion of the shielding layer DF2 may be removed by using the stripper, but the disclosure is not limited thereto. In some embodiments, the stripper may include potassium hydroxide (KOH), sodium hydroxide (NaOH), N-methylpyrrolidone (NMP), tetramethylammonium hydroxide (TMAH), dimethyl sulfoxide (DMSO) or ethanolamine (MEA).

Since the thickness T_{DF2} of the shielding layer DF2 in this embodiment is greater than the thickness T_{DF1} of the shielding layer DF1, a portion of the shielding layer DF2 may remain after the shielding layer DF1 is removed.

Step (6): A shielding layer DF3 is formed on the connection portion 420C of the circuit structure 400 located on the second surface 100S2 of the first substrate 100.

In this embodiment, the shielding layer DF3 may be formed on the second surface 100S2 of the first substrate 100 by first performing the attaching process and performing a photolithography process using the developer, so that the shielding layer DF3 may cover the connection portion 420C of the second circuit layer 420. A material of the shielding layer DF3 may be, for example, the same as or similar to the material of the shielding layer DF1, which will not be further reiterated here.

The shielding layer DF3 may be used, for example, to define a formation position of a subsequent protective layer 600, so that the protective layer 600 may be disposed on the side surface 100S3 and the second surface 100S2 of the first substrate 100, for example.

In some embodiments, the shielding layer DF3 may have a non-linear edge. For example, referring to FIG. 2B, the shielding layer DF3 has a bow-shaped edge. By enabling the shielding layer DF3 to have the non-linear edge, a surface area of the shielding layer DF3 may be increased to increase a possibility of subsequent complete removal of the shielding layer DF3. In this way, a possibility that subsequent processes will be affected by residue of the shielding layer DF3 may be reduced.

Step (7): The protective layer 600 is formed on the side surface 100S3, the second surface 100S2, and the second shielding layer DF3 of the first substrate 100.

As mentioned above, the formation position of the protective layer 600 may be defined by the configuration of the shielding layer DF3, which will not be further reiterated here. In this embodiment, the protective layer 600 may be formed on the side surface 100S3, the second surface 100S2, and the shielding layer DF3 of the first substrate 100 by performing the coating process and a curing process. For example, the protective layer 600 may be formed by first coating a curable composition using the coating process, and then performing the curing process on the curable composition. The above coating process may include a spray coating process, and the above curing process may include a light-curing process or a thermal curing process. The disclosure is not limited thereto.

It is worth noting that, in order to reduce a possibility of the protective layer 600 being removed in subsequent step (8), the protective layer 600 includes a material with relatively high chemical resistance. For example, a material of the protective layer 600 may be resistant to the corrosion by the stripper. In some embodiments, the material of the protective layer 600 may include an acrylic-based resin, a polyurethane-based resin, a synthetic rubber-based resin, or a silicone-based resin.

In this embodiment, a thickness T_{DF3} of the shielding layer DF3 is greater than a thickness T₆₀₀ of the protective layer 600. On this basis, the protective layer 600 respectively formed on the second surface 100S2 and the second shielding layer DF3 of the first substrate 100 will have a segment difference, which enables the stripper to flow in through gaps between the protective layers 600 with the segment difference during a subsequent process of removing the shielding layer DF3 to remove the shielding layer DF3.

In this embodiment, the protective layer 600 may be formed on both the side surface 100S3 and the second surface 100S2 of the first substrate 100 by performing one process (step (7)), which may reduce the number of process steps for forming the electronic device 10, and reduce process cost of the electronic device 10.

Step (8): The shielding layer DF3 is removed to expose the connection portion 420C of the circuit structure 400.

In this embodiment, the shielding layer DF3 may be removed by using the stripper, but the disclosure is not limited thereto.

In this embodiment, step (8) may further include simultaneously removing the residual shielding layer DF2.

Step (9): The circuit board 700 is bonded to the connection portion 420C of the circuit structure 400.

In this embodiment, the circuit board 700 may be bonded to the circuit structure 400 through a chip on film (COF) or a flexible printed circuit (FPC). In detail, the circuit board 700 may be bonded to the connection portion 420C of the circuit structure 400 through a chip on film COF, for example, so that the circuit board 700 may be electrically connected to the first substrate 100 and/or the second substrate 200 through the circuit structure 400. However, the disclosure is not limited thereto.

So far, the manufacturing of the electronic device 10 in this embodiment is completed, but a manufacturing method of the electronic device 10 in the disclosure is not limited thereto.

It is worth noting that the electronic device 10 in this embodiment may be applied to a tiling electronic device. Through a design of forming the protective layer 600 on both the side surface 100S3 and the second surface 100S2 of the first substrate 100, after the electronic device 10 is tiled, the circuit structure 400 may be reduced from being damaged in subsequent processes, so as to improve a yield of the tiling electronic device.

The electronic device 10 in this embodiment may, for example, have a single-board structure or a double-board structure. The disclosure is not limited thereto. Structures of an electronic device 10a and an electronic device 10b in these embodiments will be briefly introduced below with reference to FIG. 3 and FIG. 4 respectively, but the disclosure is not limited thereto.

FIG. 3 is a schematic partial cross-sectional view of an electronic device according to an embodiment of the disclosure. It is noted that some of the reference numerals and descriptions in the embodiment of FIG. 1 will apply to the embodiment of FIG. 3. The same reference numerals will represent the same or similar components and the descriptions of the same technical contents will be omitted.

In this embodiment, the electronic device 10a has a single-board structure. In detail, the electronic device 10a in this embodiment includes the first substrate 100, the display medium layer 300, the circuit structure 400, the light-shielding layer 500, the protective layer 600, the circuit board 700, and a cover plate CP.

In this embodiment, the first substrate 100 is the active device array substrate. In detail, the first substrate 100 may include, for example, the first base (not shown) and the active device (not shown). The first substrate 100 has, for example, the first surface 100S1, the second surface 100S2, and the side surfaces 100S3. The first surface 100S1 is opposite to the second surface 100S2, and the side surface 100S3 connects the first surface 100S1 and the second surface 100S2.

The first base may, for example, include a flexible base or an inflexible base. A material of the first base may include, for example, glass, plastic or a combination thereof. For example, the first base may include quartz, sapphire, polymethyl methacrylate (PMMA), polycarbonate (PC), polyimide (PI), polyethylene terephthalate (PET), or other suitable materials or a combination of the above materials. In this embodiment, the material of the first base is glass, but the disclosure is not limited thereto.

The active device is, for example, disposed on the first base. In some embodiments, the active device may include a gate (not shown), a source (not shown), a drain (not shown), and a semiconductor layer (not shown), but the disclosure is limited thereto. The gate may, for example, at least partially overlap the semiconductor layer. A region where the semiconductor layer overlaps the gate may be regarded as a channel region of the active device. The source and the drain are, for example, separated from each other, and each is electrically connected to the semiconductor layer. In some embodiments, a material of the semiconductor layer may include amorphous silicon, low temperature polycrystalline silicon (LTPS), metal oxide, other suitable materials, or a combination thereof. The metal oxide may include indium gallium zinc oxide (IGZO) or indium gallium oxide (IGO). The disclosure is not limited thereto.

The display medium layer 300 is, for example, disposed on the first substrate 100, and may include, for example, multiple light emitting elements LE, a pixel definition layer PDL, and a filling layer FL, but the disclosure is not limited thereto.

The light emitting elements LE are, for example, electrically connected to the active device in the first substrate 100 to emit light through control of the active device. In some embodiments, the light emitting elements LE may each emit various appropriate color lights (e.g., red light, green light, blue light, white light, and other color lights), IR light, or UV light, but the disclosure is not limited thereto. For example, the light emitting elements LE may include self-luminous materials, which may include diodes, organic light emitting diodes (OLEDs), and inorganic light emitting diodes (LEDs), such as mini LEDs or micro LEDs, quantum dots (QDs), QDLEDs, fluorescence, phosphor, other suitable materials or a combination of the above materials.

In this embodiment, the light emitting element LE is a flip chip micro LED, which may be electrically connected to the active device of the first substrate 100 through a connection pad PAD, but the disclosure is not limited thereto. The light emitting element LE may also be a vertical micro LED.

The pixel definition layer PDL includes, for example, multiple openings PDL_OP. The light emitting elements LE may be disposed in the corresponding openings PDL_OP. In some embodiments, a material of the pixel definition layer PDL may include an organic material, but the disclosure is not limited thereto. In other embodiments, the material of the pixel definition layer PDL may have photosensitive properties, so that it may be formed using a patterning process. However, the disclosure is not limited thereto.

The filling layer FL is, for example, disposed in the opening PDL_OP defined by the pixel definition layer PDL, and is disposed adjacent to or surrounding the light emitting element LE, for example. The filling layer FL may be used to fix or protect the light emitting element LE, for example. In some embodiments, the filling layer FL may include a transparent material, a non-transparent material, or a combination thereof. For example, a material of the filling layer FL may include an epoxy resin, acrylics, other suitable materials, or a combination thereof, but the disclosure is not limited thereto.

In some embodiments, the electronic device 10a may further include a light-shielding pattern BM1. The light-shielding pattern BM1 is, for example, disposed on or below the pixel definition layer PDL. The light-shielding pattern BM1 may be used, for example, to reduce a phenomenon of color mixing of the lights of different colors emitted by the adjacent light emitting elements LE to improve a contrast effect of the electronic device 10a at a wide viewing angle, or to absorb light irradiated toward the first substrate 100 by external ambient light to reduce a reflectivity of the electronic device 10a outdoors. In some embodiments, a material of the light-shielding pattern BM1 may include low-reflectivity metal, a metal oxide material, or a black resin organic material, but the disclosure is not limited thereto.

The circuit structure 400 is, for example, disposed on the first substrate 100. In this embodiment, the circuit structure 400 includes the first circuit layer 410, the second circuit layer 420, and the side circuit layer 430. It is worth noting that although the first circuit layer 410, the second circuit layer 420, and the side circuit layer 430 are integrally formed in FIG. 3, the first circuit layer 410, the second circuit layer 420, and the side circuit layer 430 may each be formed by different processes.

The first circuit layer 410 is, for example, disposed on the first surface 100S1 of the first substrate 100. In some embodiments, the first circuit layer 410 may be electrically connected to the active device and the light emitting element LE in the first substrate 100, but the disclosure is not limited thereto. In some embodiments, the first circuit layer 410 may be formed together with the formation of the active device or circuit in the first substrate 100.

The second circuit layer 420 is, for example, disposed on the second surface 100S2 of the first substrate 100. In this embodiment, the second circuit layer 420 includes the connection portion 420C, which may be used to be electrically connected to the circuit board 700, so that the active device in the first substrate 100 may be electrically connected to the circuit board 700. However, the disclosure is not limited thereto.

The side circuit layer 430 is, for example, disposed on the side surface 100S3 of the first substrate 100, and is electrically connected to the first circuit layer 410 and the second circuit layer 420. In this embodiment, the side circuit layer 430 may further extend to the side surface 200S3 of the second substrate 200, but the disclosure is not limited thereto.

The light-shielding layer 500 is, for example, disposed on the side circuit layer 430 of the circuit structure 400. That is, the light-shielding layer 500 is, for example, disposed on the side surface 100S3 of the first substrate 100 and covers the side circuit layer 430 of the circuit structure 400. In this embodiment, the light-shielding layer 500 is further disposed on the peripheral portion 100S2P of the second surface 100S2 of the first substrate 100. The peripheral portion 100S2P is adjacent to the junction of the side surface 100S3 and the second surface 100S2. In detail, the light-shielding layer 500 may continuously extend from the side surface 100S3 of the first substrate 100 to the second surface 100S2.

In this embodiment, an optical density (OD) value of the light-shielding layer 500 is greater than or equal to 4 and less than or equal to 8. On this basis, the light-shielding layer 500 may be used, for example, to reduce a possibility that the first substrate 100, the display medium layer 300, and/or the circuit structure 400 are observed by the user or a possibility of light leaking from the side surface 100S3 of the first substrate 100 to improve display quality of electronic device 10a. The material of the light-shielding layer 500 may include, for example, a resin (such as the acrylic-based resin, the epoxy resin, and the silicone-based resin). The resin may have a color, or the resin may have pigment particles (e.g., carbon black) or dye particles. However, the disclosure is not limited thereto.

The protective layer 600 is, for example, disposed on the light-shielding layer 500 and the second circuit layer 420 of the circuit structure 400. In this embodiment, the protective layer 600 continuously extends from the side surface 100S3 of the first substrate 100 to the second surface 100S2, and includes an opening 600_OP. The opening 600_OP exposes a portion of the second circuit layer 420.

In some embodiments, the material of the protective layer 600 may include the acrylic-based resin, the polyurethane-based resin, the synthetic rubber-based resin, or the silicone-based resin. The protective layer 600 may, for example, have relatively high hardness and/or strength to provide, for example, a scratch-resistant effect. In this embodiment, pencil hardness of the protective layer 600 is greater than or equal to 5H and less than or equal to 9H, but the disclosure is not limited thereto. In addition, the protective layer 600 may, for example, have anti-glare and/or anti-reflective effects. For example, the material of the protective layer 600 may further include multiple silicon dioxide particles, which may be used to increase diffusion of the external ambient light and/or reduce direct reflection of the external ambient light, so that the protective layer 600 has the anti-glare and/or anti-reflective effects, but the disclosure is not limited thereto.

In this embodiment, through a design that the protective layer 600 continuously extends from the side surface 100S3 of the first substrate 100 to the second surface 100S2, after the electronic device 10a is tiled, the circuit structure 400 may be reduced from being damaged in the subsequent processes, so as to improve the yield of the tiling electronic device.

The circuit board 700 is, for example, electrically connected to the second circuit layer 420 of the circuit structure 400 through the opening 600_OP. In this embodiment, the circuit board 700 may be bonded to the connection portion 420C of the circuit structure 400 through the chip on film COF, so that the circuit board 700 may be electrically connected to the first substrate 100 through the circuit structure 400. The circuit board 700 may, for example, include a driving chip (not shown), which may, for example, provide a driving signal for controlling the active device in the first substrate 100, but the disclosure is not limited thereto. The circuit board 700 may be, for example, a printed circuit board assembly (PCBA), which includes multiple electronic elements (not shown) formed by the surface-mount technology, for example, used to provide a control signal to the driving chip included in the chip on film COF, but the disclosure is not limited thereto.

The cover plate CP is, for example, disposed to face the first substrate 100. The cover plate CP may, for example, include anti-reflective, dust-proof, scratch-resistant, and water-proof intrusion effects to reduce an impact of an external environment on the internal components of the electronic device 10a, and may, for example, have a light transmittance. In some embodiments, a material of the cover plate CP may include glass. A type of glass or a composition thereof is not particularly limited, which may be, for example, aluminosilicate glass, lithium aluminosilicate glass, soda calcium silicate glass, aluminosilicate glass, quartz glass, or other glass having the light transmittance, but this disclosure is not limited thereto. In other embodiments, the material of the cover plate CP may include organic materials, which may be, for example, resin, acrylics, or other suitable organic materials. In other embodiments, the cover plate CP may include a bragg reflective layer to achieve the anti-reflective effect. In other embodiments, the cover plate CP may include an anti-pollution layer, and the anti-pollution layer includes, for example, a fluorine-containing compound.

In some embodiments, the electronic device 10a may further include an adhesion layer AL. The adhesion layer AL is, for example, disposed between the first substrate 100 and the cover plate CP in a top-view direction n of the electronic device 10a. In some embodiments, a material of the adhesion layer AL may include an optical clear resin (OCR) or an optical clear adhesive (OCA), which includes, for example, an acrylic resin, silicone resin, epoxy resin, or other suitable materials or a combination of the above materials, but the disclosure is not limited thereto. In some embodiments, in addition to a function of adhering the first substrate 100 and the cover plate CP to each other, the adhesion layer AL may also have water-blocking and oxygen barrier properties, protective properties, or other properties, but the disclosure is not limited thereto.

In some embodiments, the electronic device 10a may further include a strengthening plate ST. The strengthening plate ST is, for example, disposed on a surface of the protective layer 600 away from the second surface 100S2 of the first substrate 100. The strengthening plate ST may have insulation properties and appropriate mechanical strength, for example, to serve as a reinforcement for the first substrate 100.

FIG. 4 is a schematic partial cross-sectional view of an electronic device according to another embodiment of the disclosure. It is noted that some of the reference numerals and descriptions in the embodiment of FIG. 3 will apply to the embodiment of FIG. 4. The same reference numerals will represent the same or similar components and the descriptions of the same technical contents will be omitted.

Referring to FIG. 4, in this embodiment, the electronic device 10b is a tiling electronic device. In detail, the electronic device 10b includes a first electronic device 10b1 and a second electronic device 10b2, which may have the same or similar structures. Hereinafter, the structure of the first electronic device 10b1 is taken as an example to introduce the electronic device 10b.

In this embodiment, the first electronic device 10b1 has a double-board structure. In detail, the first electronic device 10b1 in this embodiment includes the first substrate 100, the second substrate 200, the display medium layer 300, the circuit structure 400, the light-shielding layer 500, the protective layer 600, and the circuit board 700. The descriptions of the first substrate 100, the display medium layer 300, the circuit structure 400, the light-shielding layer 500, the protective layer 600, and the circuit board 700 may be referred to the above embodiments, which will not be further reiterated here.

The second substrate 200 is, for example, disposed opposite to the first substrate 100, and may include, for example, a second base SB, a light-shielding pattern BM2, a color filter CF, a barrier layer BANK, a wavelength conversion layer WT, a package layer P, and a spacer SP.

The second substrate 200 has, for example, the first surface 200S1, the second surface 200S2, and the side surfaces 200S3. The first surface 200S1 is opposite to the second surface 200S2, and the side surface 200S3 connects the first surface 200S1 and the second surface 200S2. In this embodiment, the first surface 200S1 of the second substrate 200 faces the first surface 100S1 of the first substrate 100. In this embodiment, the light-shielding layer 500 and the protective layer 600 may be further disposed on the side surface 200S3 of the second substrate 200, and the light-shielding layer 500 is located between the protective layer 600 and the side surface 200S3 of the second substrate 200.

A material of the second base SB may be, for example, the same as or similar to the material of the first base of the first substrate 100, which will not be further reiterated here.

The light-shielding pattern BM2 and the color filter CF are, for example, disposed on the second base SB. In some embodiments, the light-shielding pattern BM2 and the color filter CF are each disposed on a surface of the second base SB facing the first substrate 100, but the disclosure is not limited thereto. In this embodiment, the light-shielding pattern BM2 is adjacent to or surrounding the color filter CF, for example. For example, the light-shielding pattern BM2 may have multiple openings to form a grid structure. The color filter CF may be disposed in the corresponding opening, but the disclosure is not limited thereto. A material of the light-shielding pattern BM2 may include, for example, a black resin, black photoresist, metal, or a combination thereof, and the disclosure is not limited thereto. On this basis, the light-shielding pattern BM2 may be used, for example, to shield internal elements and traces of the first electronic device 10b1 that are not intended to be seen by the user, so as to improve a display effect of the first electronic device 10b1. The color filter CF may include, for example, a red filter pattern, a green filter pattern, a blue filter pattern, filter patterns of other colors, or a combination thereof, thereby enabling the first electronic device 10b1 to have a color display image, but the disclosure is not limited thereto.

The barrier layer BANK and the wavelength conversion layer WT are also disposed on the second base SB, for example. In some embodiments, the barrier layer BANK and the wavelength conversion layer WT are also respectively disposed on the surface of the second base SB facing the first substrate 100, but the disclosure is not limited thereto. In this embodiment, the barrier layer BANK has multiple openings, and the openings of the barrier layer BANK may respectively correspond to the openings of the light-shielding pattern layer BM2. The wavelength conversion layer WT is, for example, disposed between the color filter CF and the light emitting element LE. In detail, in this embodiment, the wavelength conversion layer WT is disposed in the opening of the barrier layer BANK, the color filter CF is disposed between the wavelength conversion layer WT and the second base SB, and in the top-view direction n of the first electronic device 10b1, the wavelength conversion layer WT may overlap the color filter CF. In some embodiments, a material of the wavelength conversion layer WT may include quantum dot materials, phosphor materials, fluorescence materials, other suitable wavelength conversion materials, or a combination thereof. In other words, the wavelength conversion layer WT may convert light emitted by the light emitting element LE into light with another wavelength. In some embodiments, a wavelength range converted by the wavelength conversion layer WT may substantially correspond to a color of the color filter CF. For example, in this embodiment, the light emitted by each of the light emitting elements LE is the blue light. Therefore, in the top-view direction n of the first electronic device 10b1, the wavelength conversion layer WT includes a red wavelength conversion layer (not shown) and a green wavelength conversion layer (not shown). The red wavelength conversion layer may overlap a red filter layer, and the green wavelength conversion layer may overlap a green filter layer. In this embodiment, the wavelength conversion layer WT further includes a scattering layer (not shown). The scattering layer may, for example, overlap a blue filter layer. The scattering layer includes titanium dioxide particles to scatter the blue light emitted by the light emitting element LE, but the disclosure is not limited thereto. In other embodiments, a group of the light emitting elements LE may include two first light emitting elements that emit the blue light and one second light emitting element that emits the green light. On this basis, in the top-view direction n of the first electronic device 10b1, the wavelength conversion layer WT includes the red wavelength conversion layer. The red wavelength conversion layer may overlap the red filter layer to convert the blue light emitted by one of the first light emitting elements into the red light. In addition, the wavelength conversion layer WT may further include a first scattering layer (not shown) and a second scattering layer (not shown). The first scattering layer may overlap the blue filter layer to scatter the blue light emitted by another of the first light emitting elements, and the second scattering layer may overlap the green filter layer to scatter the green light emitted by the second light emitting element.

The package layer P is, for example, disposed on the second substrate 200. In this embodiment, the package layer P is disposed on a surface of the wavelength conversion layer WT facing the first substrate 100 to block the intrusion of water and oxygen into the wavelength conversion layer WT. A material included in the package layer is not particularly limited, which may include, for example, organic materials and/or organic photosensitive materials, but the disclosure is not limited thereto.

The spacer SP is, for example, disposed between the first substrate 100 and the second substrate 200 to support a gap between the first substrate 100 and the second substrate 200. In addition, the spacer SP may be used, for example, to enable the electronic device 10b have a uniform cell gap, so that each of the light emitting elements LE has substantially the same distance from the corresponding wavelength conversion layer WT. A material included in the spacer SP is not particularly limited, which may include, for example, organic materials and/or organic photosensitive materials, but the disclosure is not limited thereto.

In this embodiment, the electronic device 10b may further include the adhesion layer AL. The adhesion layer AL is, for example, disposed between the first substrate 100 and the second substrate 200 in the top-view direction n of the first electronic device 10b1. The material of the adhesion layer AL may be referred to the previous embodiment, which will not be further reiterated here.

Although not shown in FIG. 4, in this embodiment, the electronic device 10b may further include a connection component. The connection component may be in contact with the first electronic device 10b1 and the second electronic device 10b2, for example, to serve as an attachment member or a buffer member between the first electronic device 10b1 and the second electronic device 10b2, but the disclosure is not limited thereto. In some embodiments, the connection component may have a relatively small transmittance to reduce observation of presence of tiling seam lines (the connection component) of the electronic device 10b by the user, so as to improve display quality of the electronic device 10b.

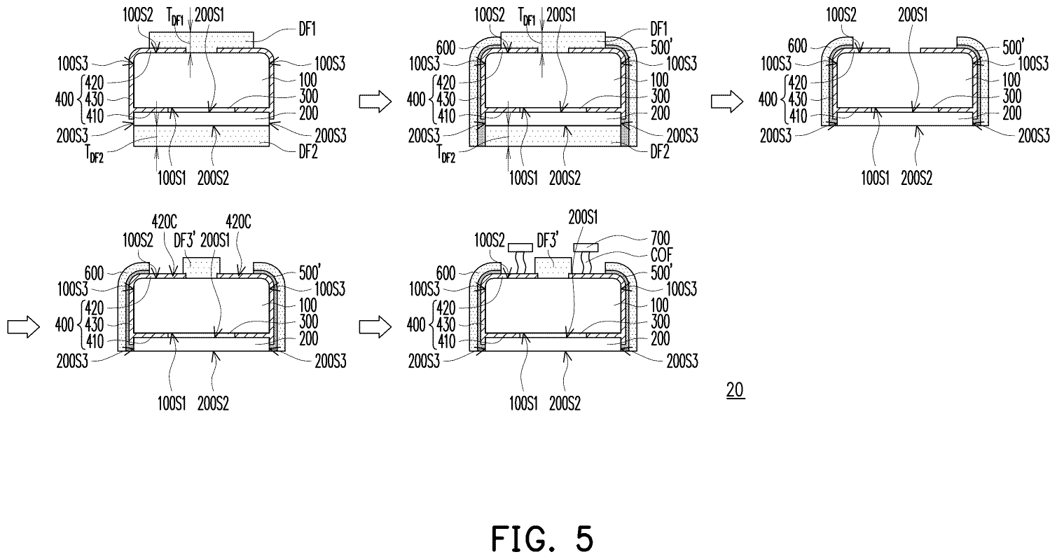

FIG. 5 is a schematic flowchart of a manufacturing method of an electronic device according to another embodiment of the disclosure. It is noted that some of the reference numerals and descriptions in the embodiment of FIG. 1 will apply to the embodiment of FIG. 5. The same reference numerals will represent the same or similar components and the descriptions of the same technical contents will be omitted.

Referring to FIG. 5, in this embodiment, the electronic device 20 may be formed by performing the following steps, but the disclosure is not limited thereto.

Step (1): The first substrate 100 and the second substrate 200 are provided, and the first substrate 100 and the second substrate 200 are bonded together.

Step (2): The circuit structure 400 is formed on the first surface 100S1, the second surface 100S2, and the side surface 100S3 of the first substrate 100.

Step (3): The shielding layer DF1 is formed on the second surface 100S2 of the first substrate 100, and the shielding layer DF2 is formed on a surface (the second surface 200S2) of the second substrate 200 away from the first substrate 100.

The above steps (1) to (3) may be referred to the previous embodiments, which will not be further reiterated here.

Step (4′): A light-shielding layer 500′ and the protective layer 600 are sequentially formed on the side surface 100S3 and the second surface 100S2 of the first substrate 100 and the side surface 200S3 and the second surface 200S2 of the second substrate 200.

The shielding layer DF1 and the shielding layer DF2 formed in Step (3) may be used, for example, to define formation positions of the light-shielding layer 500′ and the protective layer 600, so that the light-shielding layer 500′ and the protective layer 600 may be sequentially formed on the side surface 100S3 and the second surface 100S2 of the first substrate 100 and the side surface 200S3 and the second surface 200S2 of the second substrate 200.

In this embodiment, the protective layer 600 covers the light-shielding layer 500′, which may reduce a possibility of the light-shielding layer 500′ being removed in the subsequent step (5) and/or step (6). On this basis, a material included in the light-shielding layer 500′ in this embodiment is not limited by the subsequent processes and has a variety of choices.

Correspondingly, in order to reduce a possibility of the protective layer 600 being removed in the subsequent step (5) and/or step (6), the protective layer 600 includes a material with relatively high chemical resistance. For example, the material of the protective layer 600 may be resistant to the corrosion by the stripper and/or developer.

In this embodiment, the protective layer 600 may cover the first substrate 100 and the second substrate 200 together with the shielding layer DF1 and the shielding layer DF2, but the disclosure is not limited thereto.

Step (5′): The shielding layer DF1 and the shielding layer DF2 are removed.

In this embodiment, the shielding layer DF1 and the shielding layer DF2 may be removed at the same time by using the stripper, but the disclosure is not limited thereto.

Since the shielding layer DF1 and the shielding layer DF2 are removed at the same time in this step, a relationship between the thickness T_{DF2} of the shielding layer DF2 and the thickness T_{DF1} of the shielding layer DF1 may be relatively unrestricted. For example, the thickness T_{DF2} of the shielding layer DF2 may be approximately equal to the thickness T_{DF1} of the shielding layer DF1, but the disclosure is not limited thereto.

Furthermore, in this embodiment, the shielding layer DF1 and the shielding layer DF2 may be removed at the same time by performing one process (step (5′)), which may reduce the number of process steps for forming the electronic device 20, and reduce process cost of the electronic device 20.

Step (6′): A shielding layer DF3′ is formed on the second surface 100S2 of the first substrate 100. The shielding layer DF3′ exposes the connection portion 420C of the circuit structure 400.

In this embodiment, the shielding layer DF3′ may be formed on the second surface 100S2 of the first substrate 100 by first performing the attaching process and then performing the photolithography process using the developer, so that the shielding layer DF3′ is formed at a position where a portion of the original shielding layer DF1 is disposed, but the shielding layer DF3′ exposes the connection portion 420C of the second circuit layer 420.

A material of the shielding layer DF3′ may be, for example, the same as or similar to the material of the shielding layer DF1, which will not be further reiterated here.

Step (9): The circuit board 700 is bonded to the connection portion 420C of the circuit structure 400.

The above step (9) may referred to the previous embodiment, which will not be further reiterated here.

So far, the manufacturing of the electronic device 20 in this embodiment is completed, but a manufacturing method of the electronic device 20 in the disclosure is not limited thereto.

Based on the above, in the manufacturing method of the electronic device according to some embodiments of the disclosure, through the design that the shielding layer is disposed on the first substrate and exposes the peripheral portion of the second surface of the first substrate, one process may be performed to form the protective layer on both the side surface and the second surface of the first substrate, which may reduce the number of process steps for forming the electronic device according to some embodiments of the disclosure, and reduce the process cost of the electronic device. Furthermore, through the design of forming the protective layer on both the side surface and the second surface of the first substrate, the protective layer may continuously extend from the side surface to the second surface. Therefore, after the electronic device according to some embodiments of the disclosure is tiled, the circuit structure may be reduced from being damaged in the subsequent processes, so as to improve the yield of the tiling electronic device.

In addition, by disposing the shielding layer on the second substrate and enabling the edge thereof to be flush with the second surface of the second substrate, the shielding layer may reduce the phenomenon of glue bleeding in the second substrate during the subsequent processes.

In the manufacturing method of the electronic device according to other embodiments of the disclosure, by sequentially forming the light-shielding layer and the protective layer on the side surface of the first substrate and the side surface of the second substrate, the possibility of the light-shielding layer being removed during the subsequent processes may be reduced. On this basis, the material included in the light-shielding layer is not limited by the subsequent processes and has a variety of choices.

What is claimed is:

1. An electronic device, comprising:
a first substrate having a first surface, a second surface, and a side surface, wherein the first surface is opposite to the second surface, and the side surface connects the first surface and the second surface;
a first circuit layer disposed on the first surface;
a second circuit layer disposed on the second surface;
a side circuit layer disposed on the side surface and electrically connected to the first circuit layer and the second circuit layer;
a light-shielding layer disposed on the side circuit layer;
a protective layer disposed on the light-shielding layer and the second circuit layer, and continuously extending from the side surface to the second surface, wherein the protective layer comprises an opening exposing a portion of the second circuit layer; and
a circuit board electrically connected to the second circuit layer through the opening.

2. The electronic device according to claim 1, wherein the light-shielding layer is further disposed on a peripheral portion of the second surface, and the peripheral portion is adjacent to a junction of the side surface and the second surface.

3. The electronic device according to claim 1, wherein an optical density value of the light-shielding layer is greater than or equal to 4 and less than or equal to 8.

4. The electronic device according to claim 1, wherein pencil hardness of the protective layer is greater than or equal to 5H and less than or equal to 9H.

5. The electronic device according to claim 1, further comprising a second substrate and an adhesion layer, wherein the second substrate is disposed opposite to the first substrate, and the adhesion layer is disposed between the first substrate and the second substrate.

6. The electronic device according to claim 1, wherein the light-shielding layer is further disposed on a side surface of the second substrate.

7. The electronic device according to claim 6, wherein the protective layer is further disposed on the side surface of the second substrate, and the light-shielding layer is located between the protective layer and the side surface of the second substrate.

8. A manufacturing method of an electronic device, comprising:
providing a first substrate, wherein the first substrate has a first surface, a second surface, and a side surface, the first surface is opposite to the second surface, and the side surface connects the first surface and the second surface;
forming a circuit structure on the first surface, the second surface, and the side surface;
forming a first shielding layer on the second surface;
forming a light-shielding layer on the side surface;
removing the first shielding layer;
forming a second shielding layer on a connection portion of the circuit structure located on the second surface;
forming a protective layer on the side surface, the second surface, and the second shielding layer;
removing the second shielding layer to expose the connection portion of the circuit structure; and
bonding a circuit board to the connection portion of the circuit structure.

9. The manufacturing method of the electronic device according to claim 8, further comprising:
providing a second substrate;
bonding the first substrate and the second substrate; and
forming a third shielding layer on a surface of the second substrate away from the first substrate.

10. The manufacturing method of the electronic device according to claim 9, wherein a thickness of the third shielding layer is greater than a thickness of the first light-shielding layer.

11. The manufacturing method of the electronic device according to claim 9, wherein in the step of removing the second shielding layer, the method further comprises simultaneously removing the third shielding layer.

12. The manufacturing method of the electronic device according to claim 8, wherein a thickness of the second shielding layer is greater than a thickness of the protective layer.

13. The manufacturing method of the electronic device according to claim 9, wherein at least one of the first shielding layer, the second shielding layer, and the third shielding layer has a non-linear edge.

14. The manufacturing method of the electronic device according to claim 13, wherein the non-linear edge is in a bow shape.

15. A manufacturing method of an electronic device, comprising:
providing a first substrate, wherein the first substrate has a first surface, a second surface, and a side surface, the first surface is opposite to the second surface, and the side surface connects the first surface and the second surface;
forming a circuit structure on the first surface, the second surface, and the side surface;
forming a first shielding layer on the second surface;
sequentially forming a light-shielding layer and a protective layer on the side surface and the second surface;
removing the first shielding layer;
forming a second shielding layer on the second surface, wherein the second shielding layer exposes a connection portion of the circuit structure; and
bonding a circuit board to the connection portion of the circuit structure.

16. The manufacturing method of the electronic device according to claim 15, further comprising:
providing a second substrate;
bonding the first substrate and the second substrate; and
forming a third shielding layer on a surface of the second substrate away from the first substrate.

17. The manufacturing method of the electronic device according to claim 16, wherein in the step of removing the first shielding layer, the method further comprises simultaneously removing the third shielding layer.

18. The manufacturing method of the electronic device according to claim 15, wherein a thickness of the second shielding layer is greater than a thickness of the protective layer.

19. The manufacturing method of the electronic device according to claim 16, wherein at least one of the first shielding layer, the second shielding layer, and the third shielding layer has a non-linear edge.

20. The manufacturing method of the electronic device according to claim 19, wherein the non-linear edge is in a bow shape.
